(19) United States
(12) Patent Application Publication
(10) Pub. No.: US 2009/0101209 A1
(43) Pub. Date: Apr. 23, 2009

(54) Method of making an antireflective silica coating, resulting product, and photovoltaic device comprising same

(75) Inventors: Pramod K. Sharma, Ann Arbor, MI (US); Nathan P. Mellott, Northville, MI (US); Desaraju V. Varaprasad, Ann Arbor, MI (US); Yiwei Lu, Ann Arbor, MI (US); Scott V. Thomsen, South Lyon, MI (US)

Correspondence Address: NIXON & VANDERHYE, PC, 901 NORTH GLEBE ROAD, 11TH FLOOR, ARLINGTON, VA, 22203, US

(73) Assignee: Guardian Industries Corp., Auburn Hills, MI (US)

(21) Appl. No.: 11/976,079

(22) Filed: Oct. 19, 2007

(51) Int. Cl. H01L 31/04; C03C 17/23; B32B 17/00; H01L 31/18

(52) U.S. Cl. 136/261; 65/60.53; 428/429; 427/74

(57) ABSTRACT

A low-index silica coating may be made by forming silica sol including a silane and/or a colloidal silica. The silica precursor may be deposited on a substrate (e.g., glass substrate) to form a coating layer. The coating layer may then be cured and/or fired using temperature(s) of from about 550 to 700° C. A barrier undercoating including a metal oxide, such as, silica, alumina, titania, zirconia, and/or an oxynitride of silica may be deposited between the coating layer and substrate. Preferably, the barrier undercoating does not substantially affect the percent transmission or reflection of the low-index silica coating. The low-index silica based coating may be used as an antireflective (AR) film on a front glass substrate of a photovoltaic device (e.g., solar cell) or any other suitable application in certain example instances.

Certain example embodiments of this invention relate to a method of making a low-index silica coating having a barrier undercoat layer. The coating may comprise an antireflective (AR) coating and undercoat layer supported by a glass substrate for use in a photovoltaic device or the like in certain example embodiments. The undercoat layer may contain a metal oxide, such as silicon oxide, silica suboxide, alumina, alumina chloride, titania, zirconia as well as nitrides and oxynitrides of silica.

### BACKGROUND OF THE INVENTION

Glass is desirable for numerous properties and applications, including optical clarity and overall visual appearance. For some example applications, certain optical properties (e.g., light transmission, reflection and/or absorption) are desired to be optimized. For example, in certain example instances, reduction of light reflection from the surface of a glass substrate may be desirable for storefront windows, display cases, photovoltaic devices (e.g., solar cells), picture frames, other types of windows, greenhouses, and so forth.

Photovoltaic devices such as solar cells (and modules therefor) are known in the art. Glass is an integral part of most common commercial photovoltaic modules, including both crystalline and thin film types. A solar cell/module may include, for example, a photoelectric transfer film made up of one or more layers located between a pair of substrates. One or more of the substrates may be of glass, and the photoelectric transfer film (typically semiconductor) is for converting solar energy to electricity. Example solar cells are disclosed in U.S. Pat. Nos. 4,510,344, 4,806,436, 6,506,622, 5,977,477, and JP 07-122764, the disclosures of which are hereby incorporated herein by reference.

Substrate(s) in a solar cell/module are sometimes made of glass. Incoming radiation passes through the incident glass substrate of the solar cell before reaching the active layer(s) (e.g., photoelectric transfer film such as a semiconductor) of the solar cell. Radiation that is reflected by the incident glass substrate does not make its way into the active layer(s) of the solar cell, thereby resulting in a less efficient solar cell. In other words, it would be desirable to decrease the amount of radiation that is reflected by the incident substrate, thereby increasing the amount of radiation that makes its way to the active layer(s) of the solar cell. In particular, the power output of a solar cell or photovoltaic (PV) module may be dependant upon the amount of light, or number of photons, within a specific range of the solar spectrum that pass through the incident glass substrate and reach the photovoltaic semiconductor.

Because the power output of the module may depend upon the amount of light within the solar spectrum that passes through the glass and reaches the PV semiconductor, certain attempts have been made in an attempt to boost overall solar transmission through the glass used in PV modules. One attempt is the use of iron-free or “clear” glass, which may increase the amount of solar light transmission when compared to regular float glass, through absorption minimization.

Another attempt relates to the use of mono-layer AR coatings. In some instances, these AR coatings are based on the concept of imparting porosity to silica coatings by combining colloidal silica particulates with silica derived in-situ from a silane precursor. In general, the higher the porosity, the lower the refractive index of coating. It has been demonstrated earlier that by imparting sufficient porosity, silica coatings having refractive indices of 1.2-1.3 may be produced.

Sodium ions in glass may migrate to the surface over time, especially when subjected to high temperature and humidity conditions, such as those used in accelerated aging tests. This surface migration may result in an increase in alkalinity and may cause corrosion of glass surface. The adverse effects of sodium-ion migration are known, for example, in liquid crystal display applications where the liquid crystal medium can be poisoned by the sodium ions migrated through transparent conductive coatings, such as indium tin oxide coatings. Durability of an LCD may be enhanced by minimizing the migration of sodium ions by applying barrier coatings under the transparent conductive coatings. See U.S. Pat. No. 5,830,252 to Finley et al.

Sodium ions that may migrate to the surface may also penetrate into the porous coatings of silica and potentially cause erosion of coatings. This erosion may manifest itself in the form of defects in coatings after exposure to high temperature and humidity. Thus, there exists a need to improve chemical durability of mono-layer AR coatings. It is an object of this invention to provide a method to enhance chemical durability of AR coatings by applying a barrier undercoat. Materials suitable for barrier undercoat applications include metal oxides, such as, for example, silica, alumina, titania and zirconia as well oxynitrides of silica. Barrier coatings may be formed by different techniques including PVD (physical vapour deposition) such as sputtering, ion beam, e-beam deposition processes, CVD (chemical vapour deposition) such as pyrolysis of a silane gas, CLD (chemical liquid deposition) such as sol-gel process, pyrolysis of silane containing polymer films, etc. The barrier undercoat may be deposited in accordance with any well-known technique.

It is another object of this invention to provide barrier coatings that do not adversely affect the optical properties of AR coatings. Because the refractive index of soda lime glass substrate may be typically in the range of 1.51 to 1.53 and a desired AR coating index may have a refractive index of 1.24, the refractive index of the barrier undercoat may be in the range of 1.40 to 1.65. Modeling shown below in FIGS. 4 and 5, for example, may indicate that the AR coating optical performance is not sensitive to an under coat thickness as long as the under coat index is kept in the range of ±0.1 from the substrate index.

It is yet another object of this invention to provide manufacturing methods to cost effectively produce AR coatings over a barrier undercoat. While sodalime glass substrates which were previously coated with barrier undercoats could be used in this invention it may be preferable to deposit the barrier coating also in the same (or nearly the same) manufacturing step as that for depositing mono-layer AR coatings. Thus, certain embodiments of the present invention may relate to a preferred coating scheme.

It is an object of this invention to provide materials that are suitable for application as protective undercoats for single-layered AR coatings. These undercoats may enhance the chemical durability of mono-layered AR coatings.

### BRIEF SUMMARY OF EXAMPLE EMBODIMENTS OF THE INVENTION

In certain example embodiments of this invention, there is provided a method of making a low-index silica based coating. The method comprises: depositing a barrier undercoating on a glass substrate, wherein the barrier undercoating comprises a metal oxide selected from at least one of silica, alumina, titania, zirconia, and an oxynitride of silica; forming a silica precursor comprising a silica sol comprising a silane and/or a colloidal silica; depositing the silica precursor on the barrier undercoating to form a coating layer; and curing and/or firing the coating layer in an oven at a temperature of from about 550 to 700° C. for a duration of from about 1 to 10 minutes.

In certain preferred embodiments, the barrier undercoating inhibits corrosion of the glass substrate when aged. The barrier undercoating may, at least in some embodiments, not substantially affect a percent transmission and/or percent reflection.

In certain exemplary embodiments of this invention, there is a method for making a photovoltaic device including a low-index silica based coating and barrier undercoat. The method may comprise: depositing a barrier undercoating on a glass substrate, wherein the barrier undercoating comprises a metal oxide selected from at least one of silica, alumina, titania, zirconia, and an oxynitride of silica; forming a silica precursor comprising a silica sol comprising a silane and/or a colloidal silica; depositing the silica precursor on the barrier undercoating to form a coating layer; curing and/or firing the coating layer in an oven at a temperature of from about 550 to 700° C. for a duration of from about 1 to 10 minutes; and using the glass substrate with the low-index silica based coating thereon as a front glass substrate of the photovoltaic device so that the low-index silica based coating is provided on a light incident side of the glass substrate.

In certain exemplary embodiments of this invention, there is a photovoltaic device such as a solar cell comprising: a photovoltaic film, and at least a glass substrate on a light incident side of the photovoltaic film; an antireflection coating provided on the glass substrate; wherein the antireflection coating comprises at least a barrier undercoating layer provided directly on and contacting the glass substrate, the undercoating layer comprising a metal oxide selected from at least one of silica, alumina, titania, zirconia, and an oxynitride of silica; and a second layer on the barrier undercoating layer, wherein the second layer is produced using a method comprising the steps of: forming a silica precursor comprising a silica sol comprising a silane and/or a colloidal silica; depositing the silica precursor on a glass substrate to form a coating layer; curing and/or firing the coating layer in an oven at a temperature of from about 550 to 700° C. for a duration of from about 1 to 10 minutes.

In certain exemplary embodiments of this invention, there is a coated article comprising: a glass substrate; an antireflection coating provided on the glass substrate; wherein the antireflection coating comprises at least a barrier undercoating layer provided directly on and contacting the glass substrate, the undercoating layer comprising a metal oxide selected from at least one of silica, alumina, titania, zirconia, and an oxynitride of silica; and a second layer on the barrier undercoating layer, wherein the second layer is produced using a method comprising the steps of: forming a silica precursor comprising a silica sol comprising a silane and/or a colloidal silica; depositing the silica precursor on a glass substrate to form a coating layer; curing and/or firing the coating layer in an oven at a temperature of from about 550 to 700° C. for a duration of from about 1 to 10 minutes.

### BRIEF DESCRIPTION OF THE DRAWINGS

FIG. 1 is a cross sectional view of a coated article including an antireflective (AR) coating made in accordance with an example embodiment of this invention (this coated article of FIG. 1 may be used in connection with a photovoltaic device or in any other suitable application in different embodiments of this invention).

FIG. 2 is a cross sectional view of a photovoltaic device that may use the AR coating of FIG. 1.

FIG. 3 shows transmission data of coated glass substrates with and without the barrier undercoat, in accordance with exemplary embodiments, in comparison with that of an uncoated sodalime glass substrate.

FIG. 4 shows modeling of reflection of a coated glass substrate in accordance with an exemplary embodiment of the present invention.

FIG. 5 shows modeling of reflection of a coated glass substrate in accordance with an exemplary embodiment of the present invention.

### DETAILED DESCRIPTION OF EXEMPLARY EMBODIMENTS OF THE INVENTION

Referring now more particularly to the accompanying drawings in which like reference numerals indicate like parts throughout the several views.

This invention relates to antireflective (AR) coatings that may be provided for in coated articles used in devices such as photovoltaic devices, storefront windows, display cases, picture frames, greenhouses, other types of windows, and the like. In certain example embodiments (e.g., in photovoltaic devices), the AR coating may be provided on either the light incident side or the other side of a substrate (e.g., glass substrate), such as a front glass substrate of a photovoltaic device. In other example embodiments, the AR coatings described herein may be used in the context of sport and stadium lighting (as an AR coating on such lights), and/or street and highway lighting (as an AR coating on such lights).

In certain example embodiments of this invention, an improved anti-reflection (AR) coating is provided on an incident glass substrate of a solar cell or the like. This AR coating may function to reduce reflection of light from the glass substrate, thereby allowing more light within the solar spectrum to pass through the incident glass substrate and reach the photovoltaic semiconductor so that the solar cell can be more efficient. In other example embodiments of this invention, such an AR coating is used in applications other than photovoltaic devices (e.g., solar cells), such as in storefront windows, display cases, picture frames, greenhouse glass/windows, solariums, other types of windows, and the like. The glass substrate may be a glass superstrate or any other type of glass substrate in different instances.

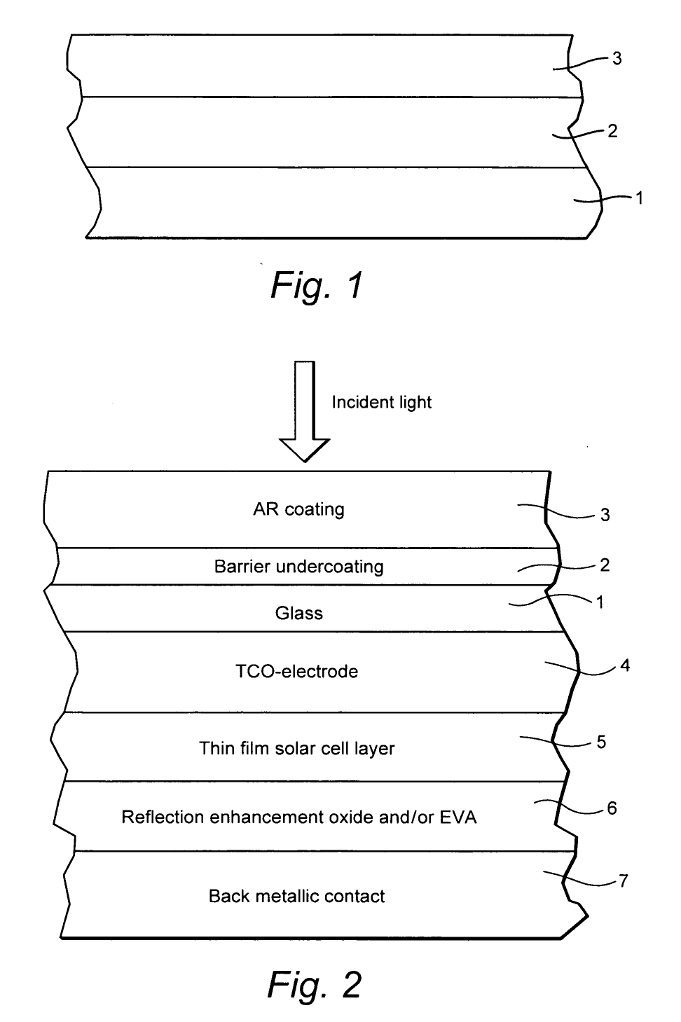

FIG. 1 is a cross sectional view of a coated article according to an example embodiment of this invention. The coated article of FIG. 1 includes a glass substrate 1, an AR coating 3, and a barrier undercoating 2.

In the FIG. 1 embodiment, the antireflective coating 3 comprises a silane and/or a colloidal silica. The AR coating may be any suitable thickness in certain example embodiments of this invention. However, in certain example embodiments, the AR coating 3 has a thickness of approximately 500 to 4000 Å after firing.

Between the glass substrate 1 and the AR coating 3, there is a barrier undercoating 2. This barrier undercoating may be any suitable thickness in certain exemplary embodiments of this invention. In various embodiments, there may be additional layers between AR coating 3 and undercoating 2 and/or between undercoating 2 and substrate 1 and/or over AR coating 3.

In certain example embodiments of this invention, high transmission low-iron glass may be used for glass substrate 1 in order to further increase the transmission of radiation (e.g., photons) to the active layer of the solar cell or the like. For example and without limitation, the glass substrate 1 may be of any of the glasses described in any of U.S. patent application Ser. Nos. 11/049,292 and/or 11/122,218, the disclosures of which are hereby incorporated herein by reference. Furthermore, additional suitable glasses include, for example (i.e., and without limitation): standard clear glass; and/or low-iron glass, such as Guardian's ExtraClear, UltraWhite, or Solar. No matter the composition of the glass substrate, certain embodiments of anti-reflective coatings produced in accordance with the present invention may increase transmission of light to the active semiconductor film of the photovoltaic device.

Certain glasses for glass substrate 1 (which or may not be patterned in different instances) according to example embodiments of this invention utilize soda-lime-silica flat glass as their base composition/glass. In addition to base composition/glass, a colorant portion may be provided in order to achieve a glass that is fairly clear in color and/or has a high visible transmission. An exemplary soda-lime-silica base glass according to certain embodiments of this invention, on a weight percentage basis, includes the following basic ingredients: SiO₂, 67-75% by weight; Na₂O, 10-20% by weight; CaO, 5-15% by weight; MgO, 0-7% by weight; Al₂O_{3,} 0-5% by weight; K₂O, 0-5% by weight; Li₂O, 0-1.5% by weight; and BaO, 0-1%, by weight.

Other minor ingredients, including various conventional refining aids, such as SO₃, carbon, and the like may also be included in the base glass. In certain embodiments, for example, glass herein may be made from batch raw materials silica sand, soda ash, dolomite, limestone, with the use of sulfate salts such as salt cake (Na₂SO₄) and/or Epsom salt (MgSO₄×7H₂O) and/or gypsum (e.g., about a 1:1 combination of any) as refining agents. In certain example embodiments, soda-lime-silica based glasses herein include by weight from about 10-15% Na₂O and from about 6-12% CaO, by weight.

In addition to the base glass above, in making glass according to certain example embodiments of the instant invention the glass batch includes materials (including colorants and/or oxidizers) which cause the resulting glass to be fairly neutral in color (slightly yellow in certain example embodiments, indicated by a positive b* value) and/or have a high visible light transmission. These materials may either be present in the raw materials (e.g., small amounts of iron), or may be added to the base glass materials in the batch (e.g., cerium, erbium and/or the like). In certain example embodiments of this invention, the resulting glass has visible transmission of at least 75%, more preferably at least 80%, even more preferably of at least 85%, and most preferably of at least about 90% (Lt D65). In certain example non-limiting instances, such high transmissions may be achieved at a reference glass thickness of about 3 to 4 mm In certain embodiments of this invention, in addition to the base glass, the glass and/or glass batch comprises or consists essentially of materials as set forth in Table 1 below (in terms of weight percentage of the total glass composition):

TABLE 1
Example Additional Materials In Glass

| Ingredient | General (Wt. %) | More Preferred | Most Preferred |
|---|---|---|---|
| total iron (expressed | 0.001-0.06% | 0.005-0.04% | 0.01-0.03% |
| as Fe₂O₃): | | | |
| cerium oxide: | 0-0.30% | 0.01-0.12% | 0.01-0.07% |
| TiO₂ | 0-1.0% | 0.005-0.1% | 0.01-0.04% |
| Erbium oxide: | 0.05 to 0.5% | 0.1 to 0.5% | 0.1 to 0.35% |

In certain example embodiments, the total iron content of the glass is more preferably from 0.01 to 0.06%, more preferably from 0.01 to 0.04%, and most preferably from 0.01 to 0.03%. In certain example embodiments of this invention, the colorant portion is substantially free of other colorants (other than potentially trace amounts). However, it should be appreciated that amounts of other materials (e.g., refining aids, melting aids, colorants and/or impurities) may be present in the glass in certain other embodiments of this invention without taking away from the purpose(s) and/or goal(s) of the instant invention. For instance, in certain example embodiments of this invention, the glass composition is substantially free of, or free of, one, two, three, four or all of: erbium oxide, nickel oxide, cobalt oxide, neodymium oxide, chromium oxide, and selenium. The phrase “substantially free” means no more than 2 ppm and possibly as low as 0 ppm of the element or material. It is noted that while the presence of cerium oxide is preferred in many embodiments of this invention, it is not required in all embodiments and indeed is intentionally omitted in many instances. However, in certain example embodiments of this invention, small amounts of erbium oxide may be added to the glass in the colorant portion (e.g., from about 0.1 to 0.5% erbium oxide).

The total amount of iron present in the glass batch and in the resulting glass, i.e., in the colorant portion thereof, is expressed herein in terms of Fe₂O₃ in accordance with standard practice. This, however, does not imply that all iron is actually in the form of Fe₂O₃ (see discussion above in this regard). Likewise, the amount of iron in the ferrous state (Fe⁺²) is reported herein as FeO, even though all ferrous state iron in the glass batch or glass may not be in the form of FeO. As mentioned above, iron in the ferrous state (Fe²⁺; FeO) is a blue-green colorant, while iron in the ferric state (Fe³⁺) is a yellow-green colorant; and the blue-green colorant of ferrous iron is of particular concern, since as a strong colorant it introduces significant color into the glass which can sometimes be undesirable when seeking to achieve a neutral or clear color.

It is noted that the light-incident surface of the glass substrate 1 may be flat or patterned in different example embodiments of this invention.

FIG. 2 is a cross-sectional view of a photovoltaic device (e.g., solar cell), for converting light to electricity, according to an example embodiment of this invention. The solar cell of FIG. 2 uses the AR coating 3, barrier undercoating 2, and glass substrate 1 shown in FIG. 1 in certain example embodiments of this invention. In this example embodiment, the incoming or incident light from the sun or the like is first incident on the AR coating 3, passes therethrough and then through barrier undercoating 2 and through glass substrate 1 and front transparent electrode 4 before reaching the photovoltaic semiconductor (active film) 5 of the solar cell. Note that the solar cell may also include, but does not require, a reflection enhancement oxide and/or EVA film 6, and/or a back metallic contact and/or reflector 7 as shown in example FIG. 2. Other types of photovoltaic devices may of course be used, and the FIG. 2 device is merely provided for purposes of example and understanding. As explained above, the AR coating 3 reduces reflections of the incident light and permits more light to reach the thin film semiconductor film 5 of the photovoltaic device thereby permitting the device to act more efficiently.

While certain of the AR coatings 3 discussed above are used in the context of the photovoltaic devices/modules, this invention is not so limited. AR coatings according to this invention may be used in other applications such as for picture frames, fireplace doors, greenhouses, and the like. Also, other layer(s) may be provided on the glass substrate under the AR coating so that the AR coating is considered on the glass substrate or on the barrier undercoating even if other layers are provided therebetween. Also, while the barrier undercoating 2 is directly on and contacting the glass substrate 1 in the FIG. 1 embodiment, it is possible to provide other layer(s) between the glass substrate and undercoating in alternative embodiments of this invention. Likewise, it is possible to provide other layer(s) between the barrier undercoating and the AR coating in alternative embodiments.

In certain embodiments, the undercoating layer may not substantially or materially alter the overall optical characteristics or significantly adversely affect reflection and/or transmission properties of mono-layered AR coatings. Thus, in certain embodiments, thickness and refractive index of the barrier undercoating may be preferably less than 1.6.

Exemplary embodiments of this invention provide a new method to produce a low index silica coating for use as the AR coating 3, with appropriate light transmission and abrasion resistance properties. Exemplary embodiments of this invention provide a method of making a coating containing a stabilized colloidal silica for use in coating 3. In certain example embodiments of this invention, the coating may be based, at least in part, on a silica sol comprising two different silica precursors, namely (a) a stabilized colloidal silica including or consisting essentially of particulate silica in a solvent and (b) a polymeric solution including or consisting essentially of silica chains.

In accordance with certain embodiments of the present invention, suitable solvents may include, for example, n-propanol, isopropanol, other well-known alcohols (e.g., ethanol), and other well-known organic solvents (e.g., toluene).

In exemplary embodiments, silica precursor materials may be optionally combined with solvents, anti-foaming agents, surfactants, etc., to adjust rheological characteristics and other properties as desired. In a preferred embodiment, use of reactive diluents may be used to produce formulations containing no volatile organic matter. Some embodiments may comprise colloidal silica dispersed in monomers or organic solvents. Depending on the particular embodiment, the weight ratio of colloidal silica and other silica precursor materials may be varied. Similarly (and depending on the embodiment), the weight percentage of solids in the coating formulation may be varied.

In certain exemplary embodiments of the present invention, spin-coating was used, although the uncured coating may be deposited in any suitable manner, including, for example, not only by spin-coating but also roller-coating, spray-coating, and any other method of depositing an uncured coating on a substrate.

In certain exemplary embodiments, the firing may occur in an oven at a temperature ranging preferably from 550 to 700° C. (and all subranges therebetween), more preferably from 575 to 675° C. (and all subranges therebetween), and even more preferably from 600 to 650° C. (and all subranges therebetween). The firing may occur for a suitable length of time, such as between 1 and 10 minutes (and all subranges therebetween) or between 3 and 7 minutes (and all subranges therebetween).

Materials suitable for barrier undercoat applications may include, in exemplary embodiments, metal oxide(s), such as, silica, alumina, titania and zirconia as well oxynitrides of silica. Depending on the particular embodiment, a barrier coating may be formed by any number of techniques, such as, for example: PVD (physical vapour deposition) such as sputtering, ion beam, e-beam deposition processes, CVD (chemical vapour deposition) such as pyrolysis of a silane gas, CLD (chemical liquid deposition) such as sol-gel process, pyrolysis of silane containing polymer films, etc.

Because the refractive index of soda lime glass substrate may be in the range of 1.51 to 1.53 and the desired AR coating index may have a refractive index of 1.24, the refractive index of the barrier undercoat may be preferably in the range of 1.40 to 1.65. In some exemplary embodiments, it is believed that the AR coating optical performance is not sensitive to an undercoat thickness as long as the undercoat refractive index is kept in the range of ±0.1 from the substrate index.

Set forth below is a description of how AR coating 3 may be made according to certain example non-limiting embodiments of this invention.

### EXAMPLE #1

In this example, an AR coating of silica was produced using the sol-gel method. The silica solution for AR coating was prepared as follows. A polymeric component of silica was prepared by using 64% wt of n-propanol, 24% wt of glycydoxylpropyltrimethoxysilane (Glymo) (available from Aldrich), 7% wt of water and 5% wt of hydrochloric acid. These ingredients were used and mixed for 24 hrs. The coating solution was prepared by using 21% wt of polymeric solution, 7% wt colloidal silica in methyl ethyl ketone supplied by Nissan Chemicals Inc, and 72% wt n-propanol. This was stirred for 2 hrs to give silica sol. The final solution is referred to as silica sol for AR coating. The silica coating was fabricated using spin coating method with 1000 rpm for 18 secs. The coating was heat treated in furnace at 625° C. for three and a half minutes.

The environmental durability of the coating was done under following conditions. Ramp—Heat from room temperature (25° C.) to 85° C. @ 100 C/hr; bring relative humidity (RH) up to 85%. Cycle 1—Dwell @ 85° C./85% RH for 1200 minutes. Ramp—Cool from 85° C. to −40° C. @ 100 C/hr; bring RH down to 0%. Cycle 2—Dwell @ −40° C./0% RH for 40 minutes. Ramp—Heat from −40° C. to 85° C. @ 100 C/hr; bring the RH up to 85%. Repeat—Repeat for 10 cycles or 240 hrs. The transmission measurements were done using PerkinElmer UV-VIS Lambda 950 before and after the environmental testing. Table 2 shows the average transmission in range of 400 nm to 1200 nm of coatings before and after the humidity and freeze testing.

### EXAMPLE #2

In this example, an barrier undercoat of silica was produced using the sol-gel method. The sol-gel method was used to fabricate the silica barrier layer by using 64% wt of n-propanol, 24% wt of glycydoxylpropyltrimethoxysilane (Glymo), 7% wt of water and 5% wt of hydrochloric acid. The silica coating was fabricated using spin coating method with 1000 rpm for 18 secs. The coating was heated in oven at 220° C. for 2.5 minutes. The refractive index of the coating was 1.4. Once the coatings became cool down to room temperature, AR coating of silica was deposited which also made from sol-gel method (from example #1). The silica coating was fabricated using spin coating method with 1000 rpm for 18 secs. The coating was heat treated in furnace at 625° C. for three and a half minutes. The environmental durability of the coating was done as mentioned in example #1. The transmission measurements were done using PerkinElmer UV-VIS Lambda 950 before and after the environmental testing. Table 2 shows the average transmission in range of 400 nm to 1200 nm of coatings before and after the humidity and freeze testing.

### EXAMPLE #3

In this example, an barrier undercoat of silica was produced using the sputtering method. The silica barrier layer had a refractive index of 1.46. The thickness of this coating was 93 nm. The top coat on the barrier coating was made by using sol-gel method. The silica sol preparation, heat treatment and environment conditions are same as mentioned in the example #1. Table 2 shows the transmission of coatings before and after the humidity and freeze testing.

### EXAMPLE #4

In this example, an barrier undercoat of silica was produced using combustion chemical vapor deposition (CCVD). The combustion chemical vapor deposition method was used to fabricate the silica barrier layer for AR coating. The precursor used in the CCVD method was HMDSO (hexamethyldisiloxane) using propane as fuel at the temperature of 300° C. The top coat on the barrier coating was made by using sol-gel method. The silica sol preparation, heat treatment and environment conditions are same as mentioned in the example #1. Table 2 shows the transmission of coatings before and after the humidity and freeze testing.

### EXAMPLE #5

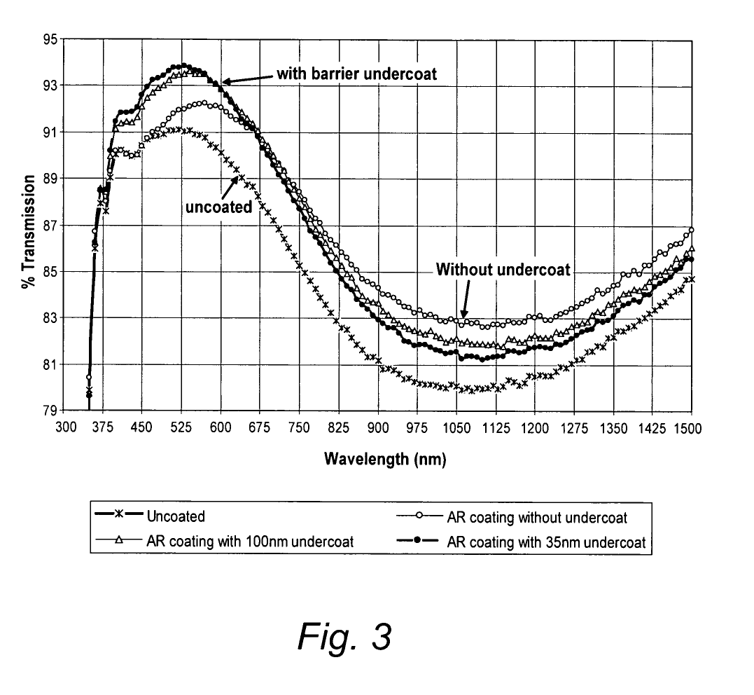

In this example, an barrier undercoat of silica was formed from silane. A UV curable monomer mixture of Cyracure UVR-6107 (available from Dow Chemical Co.) containing 4 wt % of photoinitiator, Cyracure UVI-6992 (available from Dow Chemical Co.) was combined with 5 wt % of Glymo to form a coating composition to deposit a barrier undercoat. An AR coating composition was prepared by combining the UV curable monomer mixture with colloidal silica dispersion IPA-ST-UP (obtained from Nissan Chemicals) and Glymo. The total SiO₂ was kept at 2% by eight of the coating composition which contained 60 parts of colloidal silica and 40 parts of silica formed from Glymo. Two sodalime glass substrates were first coated with the barrier undercoat composition by using spin coating technique at 1700 rpm and 3500 rpm for 30 seconds followed by exposure to UV radiation for about 40 seconds. The two coated glass substrates and an additional uncoated sodalime glass substrate were then coated with the AR coating composition at 3500 rpm for 30 seconds and the wet coatings were cured by exposure to UV to form cross-linked polymer films. The coated glass substrates were then subjected to heat treatment at 625° C. for 5 minutes to form silica coatings. The thickness of the AR coating was determined to be about 145 nm and the thickness of barrier coatings on the first substrate was 100 nm while it was 35 nm on the second substrate. Transmission data of coated glass substrates with and without the barrier undercoat is shown in FIG. 3 in comparison with that of an uncoated sodalime glass substrate.

### EXAMPLE #6

In this example, the combustion chemical vapor deposition method was used to fabricate the AlCl₃ barrier layer for the AR coating. The precursor used in the CCVD method was aluminum chloride. The top coat on the barrier coating was made by using sol-gel method. The silica sol preparation, heat treatment and environment conditions are same as mentioned in the example #1. Table 2 shows the transmission of coatings before and after the humidity and freeze testing. The glass substrate of this coating is 1.6 mm thick.

TABLE 2
Transmission before and after humidity testing
Percentage Transmission

| Sample | Before | After | Change |
|---|---|---|---|
| Uncoated glass | 84.90 | 84.17 | 0.71 |
| AR Coating Without Barrier Layer | 86.96 | 73.57 | 13.39 |
| (Example #1) | | | |
| AR Coating with Silica Barrier by Sol-Gel | 86.08 | 77.19 | 8.89 |
| (Example #2) | | | |
| AR Coating with Silica Barrier by Sputtering | 87.41 | 86.50 | 0.90 |
| (Example #3) | | | |
| AR Coating with Silica Barrier by CCVD | 87.30 | 85.98 | 1.32 |
| (Example #4) | | | |
| AR Coating with AlCl₃ Barrier by CCVD | 89.28 | 87.55 | 1.73 |
| (Example #6) | | | |

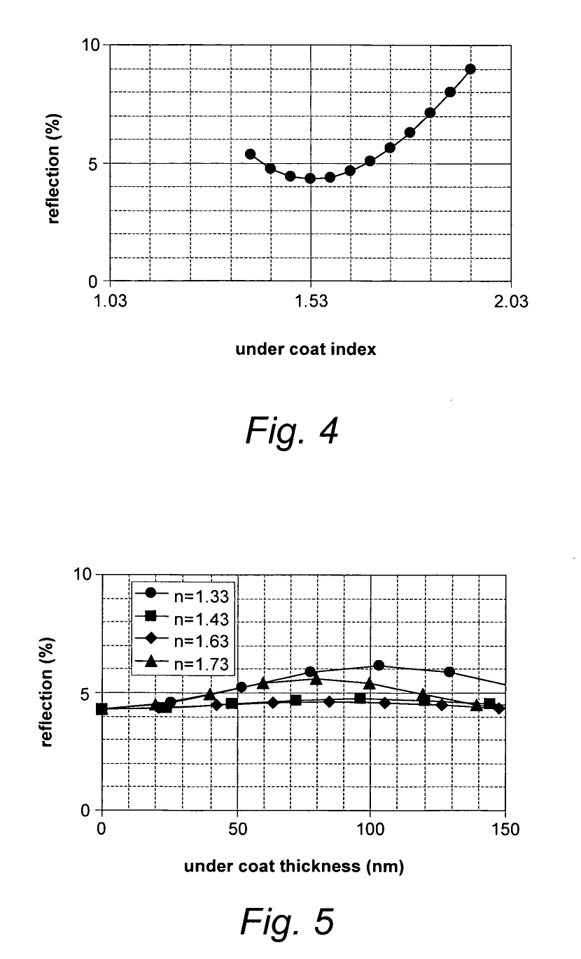

FIG. 4 shows reflection at 550 nm from a piece of 3 mm thick soda lime clear glass having a two-layered AR coating on the first surface. The AR coating consists of a quarter wavelength low index (n=1.24) overcoat and a quarter wavelength undercoat having an index higher than 1.24. The undercoat may promote the durability of AR coating and block the diffusion of sodium from glass substrate.

FIG. 5 shows reflection at 550 nm from a piece of 3 mm thick soda lime clear glass having a two-layered AR coating on the first surface. The AR coating consists of a quarter wavelength low index (n=1.24) overcoat and an undercoat having different index and different thickness.

All described and claimed numerical values and ranges are approximate and include at least some degree of variation.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

1. A method of making a low-index silica based coating, the method comprising:
depositing a barrier undercoating on a glass substrate, wherein the barrier undercoating comprises a metal oxide selected from at least one of silica, alumina, titania, zirconia, and an oxynitride of silica;
forming a silica precursor comprising a silica sol comprising a silane and/or a colloidal silica;
depositing the silica precursor on the barrier undercoating to form a coating layer; and
curing and/or firing the coating layer in an oven at a temperature of at least about 550° C. for a duration of from about 1 to 10 minutes.

2. The method of claim 1, wherein either step of depositing comprises spin-coating, roller-coating, or spray-coating.

3. The method of claim 1, wherein the barrier undercoating is formed by physical vapour deposition, chemical vapour deposition, or chemical liquid deposition.

4. The method of claim 1, wherein the barrier undercoating has a refractive index less than 1.6.

5. The method of claim 1, wherein the barrier undercoating inhibits corrosion of the glass substrate when aged.

6. A method of making a photovoltaic device comprising a photoelectric transfer film, at least one electrode, and the low-index coating, wherein the method of making the photovoltaic device comprises making the low-index coating according to claim 1, and wherein the low-index coating is provided on a light incident side of a front glass substrate of the photovoltaic device.

7. A method of making a photovoltaic device including a low-index silica based coating used in an antireflective coating, the method comprising:
depositing a barrier undercoating on a glass substrate, wherein the barrier undercoating comprises a metal oxide selected from at least one of silica, alumina, titania, zirconia, and an oxynitride of silica;
forming a silica precursor comprising a silica sol comprising a silane and/or a colloidal silica;
depositing the silica precursor on the barrier undercoating to form a coating layer;
curing and/or firing the coating layer in an oven at a temperature of from about 550 to 700° C. for a duration of from about 1 to 10 minutes; and
using the glass substrate with the low-index silica based coating thereon as a front glass substrate of the photovoltaic device so that the low-index silica based coating is provided on a light incident side of the glass substrate.

8. The method of claim 7, wherein either step of depositing comprises spin-coating, roller-coating, or spray-coating.

9. The method of claim 7, wherein the barrier undercoating is formed by physical vapour deposition, chemical vapour deposition, or chemical liquid deposition.

10. The method of claim 7, wherein the low-index coating has a percent transmission and/or percent reflection that is not substantially affected by the barrier undercoating.

11. A photovoltaic device comprising:
a photovoltaic film, and at least a glass substrate on a light incident side of the photovoltaic film;
an antireflection coating provided on the glass substrate;
wherein the antireflection coating comprises at least a barrier undercoating layer provided directly on and contacting the glass substrate, the undercoating layer comprising a metal oxide selected from at least one of silica, alumina, titania, zirconia, and an oxynitride of silica; and a second layer on the barrier undercoating layer, wherein the second layer is produced using a method comprising the steps of: forming a silica precursor comprising a silica sol comprising a silane and/or a colloidal silica; depositing the silica precursor on a glass substrate to form a coating layer; curing and/or firing the coating layer in an oven at a temperature of from about 550 to 700° C. for a duration of from about 1 to 10 minutes.

12. The photovoltaic device of claim 11, wherein the barrier undercoating layer comprises silica and has a refractive index of less than 1.6.

13. The photovoltaic device of claim 11, wherein the antireflection coating has a percent transmission and/or percent reflection that is not substantially affected by the barrier undercoating.

14. A coated article comprising:
a glass substrate;
an antireflection coating provided on the glass substrate;
wherein the antireflection coating comprises at least a barrier undercoating layer provided directly on and contacting the glass substrate, the undercoating layer comprising a metal oxide selected from at least one of silica, alumina, titania, zirconia, and an oxynitride of silica; and a second layer on the barrier undercoating layer, wherein the second layer is produced using a method comprising the steps of: forming a silica precursor comprising a silica sol comprising a silane and/or a colloidal silica; depositing the silica precursor on a glass substrate to form a coating layer; curing and/or firing the coating layer in an oven at a temperature of from about 550 to 700° C. for a duration of from about 1 to 10 minutes.

15. The coated article of claim 14, wherein the barrier undercoating layer comprises silica and has a refractive index of less than 1.6.

16. The coated article of claim 14, wherein the antireflection coating has a percent transmission and/or percent reflection that is not substantially affected by the barrier undercoating.
